(19) United States
(12) Patent Application Publication
(10) Pub. No.: US 2016/0020144 A1
(43) Pub. Date: Jan. 21, 2016

(54) METHOD FOR FABRICATING SEMICONDUCTOR DEVICE

(71) Applicant: UNITED MICROELECTRONICS CORP., Hsin-Chu City (TW)

(72) Inventors: Chia-Lin Lu, Taoyuan County (TW); Chun-Lung Chen, Tainan City (TW); Kun-Yuan Liao, Hsin-Chu City (TW); Feng-Yi Chang, Tainan City (TW); Chieh-Te Chen, Kaohsiung City (TW)

(21) Appl. No.: 14/332,375

(22) Filed: Jul. 15, 2014

(51) Int. Cl. H01L 21/768; H01L 29/66; H01L 21/285; H01L 23/532; H01L 21/311; H01L 29/78; H01L 23/528

(52) U.S. Cl. CPC H01L 21/76877; H01L 29/78; H01L 29/66568; H01L 23/528; H01L 23/53228; H01L 21/76802; H01L 21/7684; H01L 21/31116; H01L 21/31144; H01L 21/28568; H01L 21/76897

(57) ABSTRACT

A method for fabricating semiconductor device is disclosed. The method includes the steps of: providing a substrate having at least a device thereon; forming a dielectric layer on the device and the substrate; forming a first mask layer on the dielectric layer; removing part of the first mask layer and part of the dielectric layer for forming a patterned first mask layer on the dielectric layer; covering a hard mask on the patterned first mask layer and the dielectric layer; partially removing the hard mask for forming a spacer adjacent to the patterned first mask layer and the dielectric layer; forming a contact hole adjacent to the spacer; filling the contact hole with a metal layer; and planarizing the metal layer for forming a contact plug, wherein the contact plug contacts the dielectric layer and the spacer simultaneously.

### BACKGROUND OF THE INVENTION

1. Field of the Invention

The invention relates to a method for fabricating semiconductor device, and more particularly, to a method of using re-cap hard mask technique to modulate critical dimension for contact plugs.

2. Description of the Prior Art

Along with the continuous miniaturization of the Integrated Circuits (IC), the line width of interconnections and the feature size of semiconductor devices have continuously shrunk. In general, discrete devices in integrated circuits are connected to each other through contact plugs (or contact slots) and interconnective structures.

Conventional approach for fabricating contact plugs or interconnective structures is typically accomplished by first using a patterned hard mask as hard mask to form a plurality of contact holes in a dielectric layer above the substrate, and then depositing a metal into the contact holes for forming contact plugs. Unfortunately, the hard mask used is often consumed during the etching process for forming contact holes, and the utilization of such trimmed hard mask in most circumstances would result in smaller window, thereby increasing the difficulty to achieve exposures in larger critical dimensions.

### SUMMARY OF THE INVENTION

It is therefore an objective of the present invention to provide a novel method for resolving aforementioned issues.

According to a preferred embodiment of the present invention, a method for fabricating semiconductor device is disclosed. The method includes the steps of: providing a substrate having at least a device thereon; forming a dielectric layer on the device and the substrate; forming a first mask layer on the dielectric layer; removing part of the first mask layer and part of the dielectric layer for forming a patterned first mask layer on the dielectric layer; covering a hard mask on the patterned first mask layer and the dielectric layer; partially removing the hard mask for forming a spacer adjacent to the patterned first mask layer and the dielectric layer; forming a contact hole adjacent to the spacer; filling the contact hole with a metal layer; and planarizing the metal layer for forming a contact plug, wherein the contact plug contacts the dielectric layer and the spacer simultaneously.

According to another aspect of the present invention, a semiconductor device includes: a substrate having at least a device thereon; a dielectric layer on the device and the substrate; a contact plug in the dielectric layer and electrically connected to the device; and a spacer between the contact plug and the dielectric layer, in which the contact plug contacts the dielectric layer and the spacer simultaneously.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 illustrate a method for fabricating a semiconductor device according to a preferred embodiment of the present invention.

FIGS. 7-9 illustrate approaches for fabricating contact holes according to additional embodiments of the present invention.

### DETAILED DESCRIPTION

Referring to FIGS. 1-6, FIGS. 1-6 illustrate a method for fabricating a semiconductor device according to a preferred embodiment of the present invention. As shown in FIG. 1, a substrate 12, such as a substrate composed of monocrystalline silicon, gallium arsenide (GaAs) or other known semiconductor material is provided. At least a device 14 is then formed on the substrate 12, in which the device 14 is preferably a metal-oxide semiconductor (MOS) transistor. The MOS transistor could be a PMOS transistor, a NMOS transistor, a CMOS transistor, a meta-gate transistor, a fin field effect transistor (Fin-FET), or any other types of transistors. Preferably, the MOS transistor could include typical transistor structures including a gate structure 16, a spacer 18, and a source/drain region 20. Elements such as lightly doped drains, epitaxial layers, salicides, and contact etch stop layer (CESL) may also be fabricated depending on the demand of the process, and as the fabrication of these elements are well known to those skilled in the art, the details of which is not explained herein for the sake of brevity.

Next, a dielectric layer, preferably an interlayer dielectric (ILD) layer 22 is formed on the device 14 and the substrate 12. In this embodiment, the ILD layer 22 could be composed of three layers, including a dielectric layer deposited by sub-atmospheric pressure chemical vapor deposition (SACVD), a phosphosilicate glass (PSG) layer, and a tetraethylorthosilicate (TEOS) layer. The depth of the entire interlayer dielectric layer 22 is a few thousand Angstroms, and preferably at approximately 3150 Angstroms; the depth of the dielectric layer is around several thousands of Angstroms, and preferably at 250 Angstroms; the depth of the PSG layer is between 1000 Angstroms to 3000 Angstroms, and preferably at 1900 Angstroms; and the depth of the TEOS layer is between 100 Angstroms to 2000 Angstroms, and preferably at 1000 Angstroms. In addition to be a composite material layer, the ILD layer 22 could also be a single material layer, and in addition to the aforementioned materials, the ILD layer 22 could also include undoped silicate glass (USG), borophosposilicate glass (BPSG), low-k dielectric material such as porous dielectric material, SiC, SiON, or combination thereof.

After forming the ILD layer 22 and an optional oxide layer 24 on top of the ILD layer 22, a first mask layer 26 and an optional second mask layer 28 are formed on the oxide layer 24, in which the first mask layer 26 and the second mask layer 28 are preferably composed of different material. The first mask layer 26 is preferably selected from an advanced pattern film (APF) fabricated by Applied Materials Inc., and the second mask layer 28 is composed of silicon dioxide, but not limited thereto. It should be noted that even though the first mask layer 26 and the second mask layer 28 are preferably composed dielectric materials, these two mask layers 26 and 28 could also be composed of metals depending on the demand of the product, which is also within the scope of the present invention.

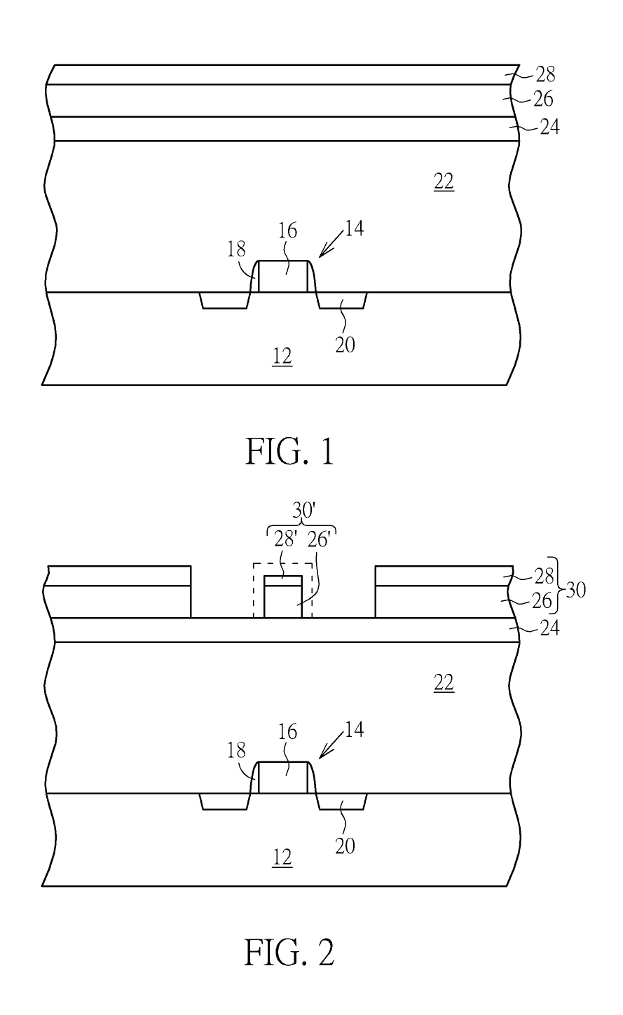

Next, as shown in FIG. 2, a patterning process is conducted to pattern the first mask layer 26 and the second mask layer 28 into a patterned mask 30′ and one or more patterned masks 30 adjacent to the patterned mask 30′. The patterned mask 30′ preferably includes a patterned first mask layer 26′ and a patterned second mask layer 28′ while each of the patterned masks 30 includes a patterned first mask layer 26 and a patterned second mask layer 28. The patterning process could be accomplished by first conducting one or more photo-etching processes to partially remove the second mask layer 28 for forming a plurality of patterned second mask layers 28, and another etching is conducted thereafter by using the patterned second mask layers 28 as mask to partially remove the first mask layer 26 underneath for forming the patterned masks 30′ and 30. It should be noted that as the patterned second mask layer 28′ of the patterned mask 30′ is typically consumed or trimmed more than adjacent patterned second mask layers 28 during the aforementioned photo-etching process, the dimension of the patterned second mask layer 28′ would be transferred to the patterned first mask layer 26′ underneath and the overall dimension of the patterned mask 30′ would therefore be substantially smaller than a regular sized pattern as represented by the dotted line.

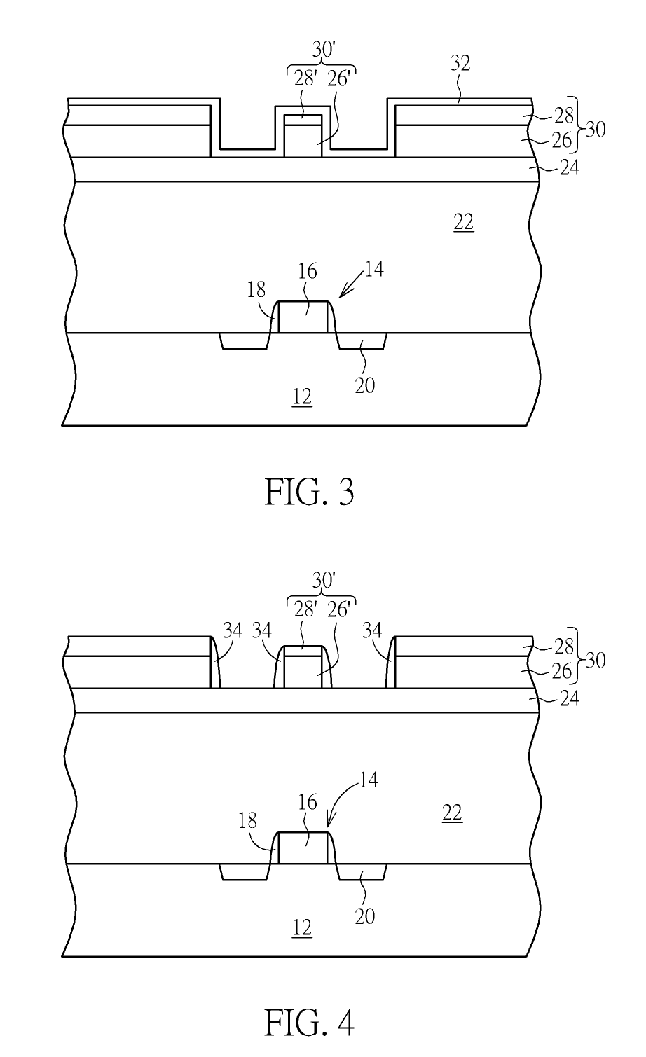

After the patterning process, as shown in FIG. 3, a hard mask 32 is covered on the patterned masks 30′ and 30 and the ILD layer 22. The material of the hard mask 32 could be the same as or different from the material of the patterned first mask layer 26 and/or the patterned second mask layer 28. For instance, the hard mask 32 could be composed of silicon nitride or silicon oxide, or any other dielectric material, but not limited thereto.

Next, as shown in FIG. 4, an etching process, preferably a dry etching process is conducted to partially remove the hard mask 32 for forming a spacer 34 adjacent to each of the patterned masks 30 and 30′.

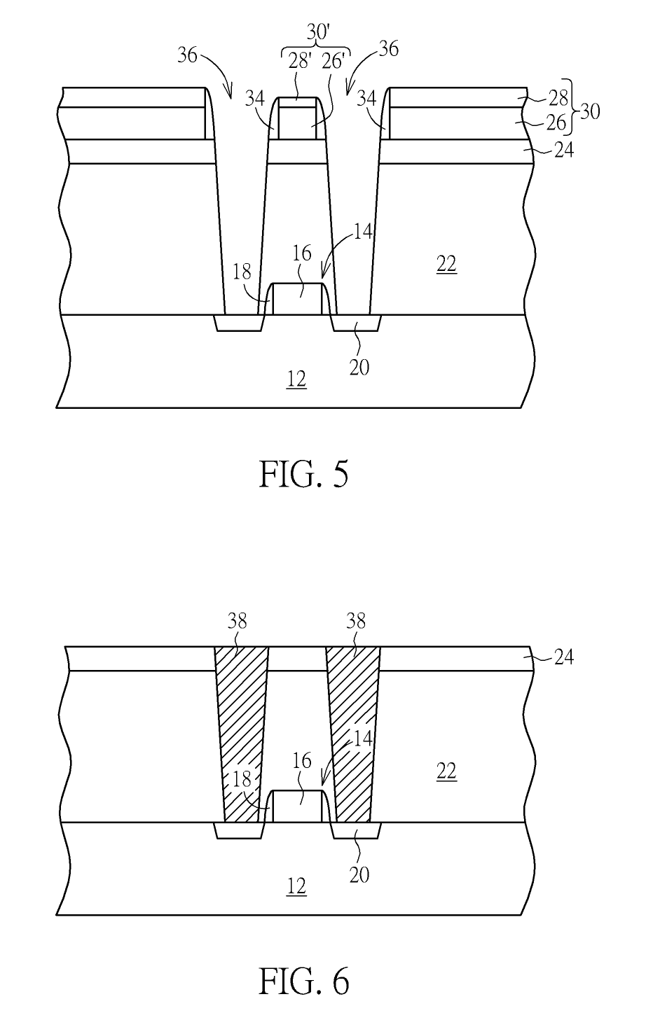

As shown in FIG. 5, another etching process is conducted by using the patterned masks 30 and 30′ and the spacers 34 as mask to partially remove the oxide layer 24 and the ILD layer 22 for forming a plurality of contact holes 36 adjacent to the spacers 34.

After removing the patterned masks 30′ and 30 and the spacers 34, as shown in FIG. 6, a barrier/adhesive layer (not shown), a seed layer (not shown) and a conductive layer (not shown) are sequentially formed to cover the oxide layer 24 and fill the contact holes 36, in which the barrier/adhesive layer are formed conformally along the surfaces of the contact holes 36 while the conductive layer is filled completely into the contact holes 36. The barrier/adhesive layer may be consisted of tantalum (Ta), titanium (Ti), titanium nitride (TiN) or tantalum nitride (TaN), tungsten nitride (WN) or a suitable combination of metal layers such as Ti/TiN, but is not limited thereto. A material of the seed layer is preferably the same as a material of the conductive layer, and a material of the conductive layer may include a variety of low-resistance metal materials, such as aluminum (Al), titanium (Ti), tantalum (Ta), tungsten (W), niobium (Nb), molybdenum (Mo), copper (Cu) or the likes, preferably tungsten or copper, and more preferably tungsten. Next, a planarizing process, such as a chemical mechanical polishing (CMP) process or an etching back process or combination thereof, can be performed to partially remove the barrier/adhesive layer, the seed layer and the conductive layer outside the contact holes 36 so that a top surface of a remaining conductive layer and the top surface of the oxide layer 24 are coplanar, thereby forming a plurality of contact plugs 38 electrically connected to the source/drain region 20 of the device 14. This completes the fabrication of semiconductor device according to a preferred embodiment of the present invention.

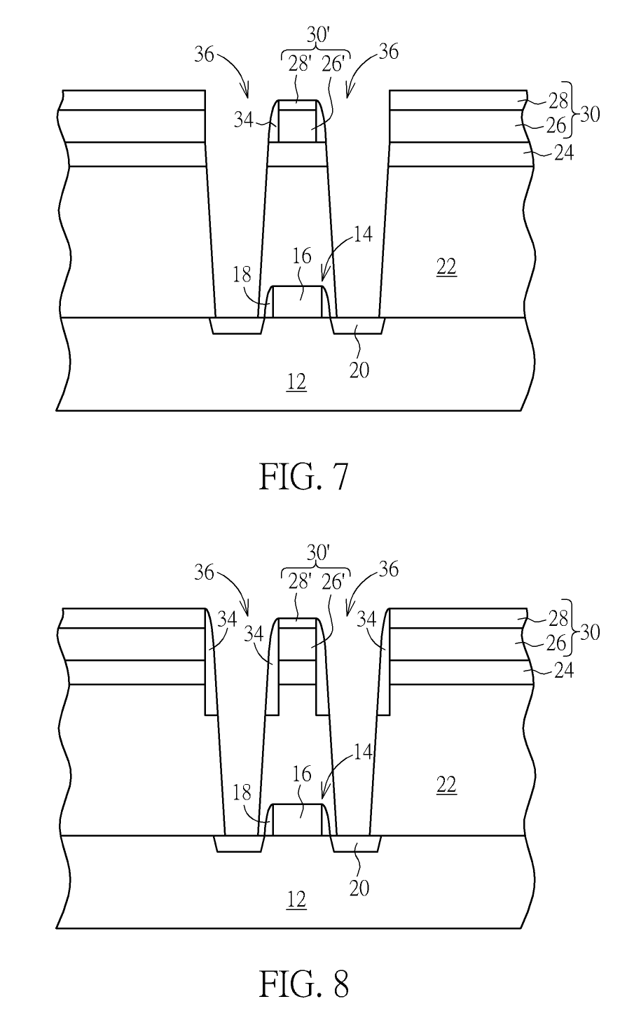

Referring to FIG. 7, which illustrates an approach for fabricating contact holes according to an embodiment of the present invention. In this embodiment, the spacers 34 adjacent to the sidewalls of the patterned masks 30 could be removed as soon as the fabrication steps shown in FIGS. 1-4 are completed. After removing the spacers 34 from the patterned mask 30 while spacers 34 on the sidewalls of the patterned mask 30′ are still retained, an etching process is conducted by using the patterned masks 30 with no spacer and the patterned mask 30′ with spacer 34 as mask to partially remove the oxide layer 24 and ILD layer 22 for forming a plurality of contact holes 36 adjacent to the spacers 34 and patterned masks 30. The steps for forming contact plugs thereafter could be accomplished by repeating the steps described in the aforementioned embodiment, and the details of which are not explained herein for the sake of brevity.

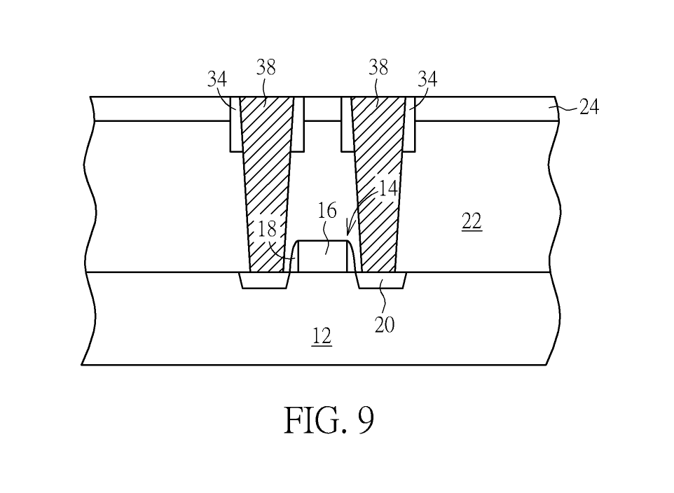

Referring to FIGS. 8-9, which illustrates another approach for fabricating contact holes according to an embodiment of the present invention. In this embodiment, instead of only removing part of the first mask layer 26 and second mask layer 28 as shown in FIG. 2, part of the oxide layer 24 and part of the ILD layer 22 could also be removed thereafter. After part of the four layers 28, 26, 24, 22 are removed, a spacer formation similar to the formation of the spacer 34 in FIG. 4 is conducted by first covering a hard mask on the patterned first mask layers 26 and 26′, the patterned second mask layers 28 and 28′, and the ILD layer 22, and a dry etching process is conducted to partially remove the hard mask for forming a plurality of spacers 34 on the sidewalls of the patterned mask 30′, the patterned masks 30, the oxide layer 24, and the ILD layer 22. As shown in FIG. 8, an etching process is then conducted by using the patterned masks 30′ and 30 and the spacers 34 as mask to partially remove the oxide layer 24 and ILD layer 22 for forming a plurality of contact holes 36 exposing the source/drain region 20.

After forming the contact holes 36, as shown in FIG. 9, a contact formation process could be conducted by repeating the steps described in the aforementioned embodiment to form a plurality of contact plugs 38 electrically connected to the source/drain region 20, and the details of which are not explained herein for the sake of brevity. It should be noted that after the contact plugs 38 are formed, part of the spacers 34 would be remained between the contact plugs 38 and the adjacent oxide layer 24 and ILD layer 22 . From another perspective, the contact plugs 38 preferably contact both the spacer 34 and the ILD layer 22 simultaneously, or the bottom surface of the spacer 34 contacts the ILD layer 22 directly.

Overall, the present invention employs a re-cap hard mask technique to modulate the critical dimension of the mask layer used for forming contact plugs so that the dimension of the patterned mask trimmed or shrunk from the etching process would not affect the formation of the contacts plugs conducted afterwards. Preferably, the re-cap hard mask technique is accomplished by first covering a hard mask on a patterned mask situating on ILD layer of a substrate, partially removing the hard mask to form a spacer adjacent to the patterned mask, and using both the patterned mask and the spacer to form a contact hole in the substrate adjacent to the spacer. By using the width of the spacer to expand the overall dimension of the patterned mask, the present invention could maintain a desirable critical dimension for the patterned mask while ensuring the quality for forming the contact plugs.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate, wherein the substrate comprises at least a device thereon;
forming a dielectric layer on the device and the substrate;
forming a first mask layer on the dielectric layer;
removing part of the first mask layer and part of the dielectric layer for forming a patterned first mask layer on the dielectric layer;
covering a hard mask on the patterned first mask layer and the dielectric layer;
partially removing the hard mask for forming a spacer adjacent to the patterned first mask layer and the dielectric layer;
forming a contact hole adjacent to the spacer;
filling the contact hole with a metal layer; and
planarizing the metal layer for forming a contact plug, wherein the contact plug contacts the dielectric layer and the spacer simultaneously.

2. The method of claim 1, wherein the dielectric layer comprises an interlayer dielectric (ILD) layer.

3. The method of claim 1, wherein the first mask layer comprises an advanced patterning film (APF).

4. The method of claim 1, further comprising performing a dry etching process to partially remove the hard mask for forming the spacer.

5. The method of claim 1, further comprising:
forming the first mask layer and a second mask layer on the dielectric layer;
removing part of the first mask layer, part of the second mask layer, and part of the dielectric layer for forming the patterned first mask layer and a patterned second mask layer on the dielectric layer;
covering the hard mask on the patterned first mask layer, the patterned second mask layer, and the dielectric layer; and
partially removing the hard mask for forming the spacer adjacent to the patterned first mask layer, the patterned second mask layer, and the dielectric layer.

6. The method of claim 5, wherein the first mask layer and the second mask layer comprise different material.

7. The method of claim 1, wherein the device comprises a MOS transistor.

8. The method of claim 7, further comprising forming the contact hole adjacent to the spacer for connecting to a source/drain region of the MOS transistor.

9. The method of claim 1, further comprising removing the patterned first mask layer and the spacer after forming the contact hole.

10. The method of claim 1, wherein the metal layer comprises copper.

11. A semiconductor device, comprising:
a substrate, wherein the substrate comprises at least a device thereon;
a dielectric layer on the device and the substrate;
a contact plug in the dielectric layer and electrically connected to the device; and
a spacer between the contact plug and the dielectric layer, wherein the contact plug contacts the dielectric layer and the spacer simultaneously.

12. The semiconductor device of claim 11, wherein the dielectric layer comprises an interlayer dielectric (ILD) layer.

13. The semiconductor device of claim 11, further comprising an oxide layer on the dielectric layer and around the contact plug.

14. The semiconductor device of claim 13, wherein the spacer is between the contact plug and the oxide layer.

15. The semiconductor device of claim 11, wherein the device comprises a MOS transistor.

16. The semiconductor device of claim 11, wherein a bottom surface of the spacer contacts the dielectric layer.
